(19) United States
(12) Patent Application Publication
(10) Pub. No.: US 2021/0193533 A1
(43) Pub. Date: Jun. 24, 2021

(54) SEMICONDUCTOR DEVICE, MANUFACTURING METHOD THEREOF, AND ELECTRONIC DEVICE INCLUDING THE DEVICE

(71) Applicant: Institute of Microelectronics, Chinese Academy of Sciences, Beijing (CN)

(72) Inventors: Huilong ZHU, Poughkeepsie, NY (US); Yongkui ZHANG, Beijing (CN); Xiaogen YIN, Beijing (CN); Chen Li, Beijing (CN); Yongbo LIU, Beijing (CN); Kunpeng JIA, Beijing (CN)

(21) Appl. No.: 17/250,770

(22) PCT Filed: Oct. 31, 2018
(86) PCT No.: PCT/CN2018/113052

§ 371 Date: Mar. 2, 2021

(30) Foreign Application Priority Data
Oct. 26, 2018 (CN) 201811265735.1

(51) Int. Cl. H01L 21/8238; H01L 27/092

(52) U.S. Cl. CPC H01L 21/823807; H01L 21/823814; H01L 21/823842; H01L 27/0925; H01L 21/823885

(57) ABSTRACT

The disclosed technology provides a semiconductor device, a manufacturing method thereof, and an electronic device including the device. An example semiconductor device includes a substrate; a first device and a second device on the substrate. Each of the first device and the second device include a first source/drain layer, a channel layer, and a second source layer that are sequentially stacked, from bottom to top, on the substrate, and a gate stack around at least a part of an outer periphery of the channel layer, with sidewalls of the respective channel layers of the first device and the second device extending at least partially along different crystal planes or crystal plane families.

### CROSS-REFERENCE TO RELATED APPLICATIONS

This application claims priority to Chinese Patent Application No. 201811265735.1 which is titled “Semiconductor Device, Manufacturing Method thereof, and Electronic Device including the Device” and which was filed on Oct. 26, 2018, the disclosure of which is hereby incorporated herein by reference in its entirety.

### BACKGROUND OF THE DISCLOSED TECHNOLOGY

### Field

The disclosed technology relates to a field of semiconductors, and in particular to a vertical semiconductor device and a manufacturing method thereof, and an electronic device including the semiconductor device.

### Description of the Related Technology

In a horizontal device such as a metal oxide semiconductor field effect transistor (MOSFET), source, gate, and drain are arranged in a direction substantially parallel to a surface of a substrate. Due to this arrangement, an area occupied by the horizontal device is reduced, and areas occupied by the source, drain and gate are generally required to be reduced, making device performances worse (for example, the power consumption and resistance increase), such that it is not easy for the area of the horizontal device to be further reduced. In contrast, in a vertical device, the source, gate, and drain are arranged in a direction substantially perpendicular to a surface of the substrate. Therefore, compared to the horizontal device, it is easier for an area occupied by the vertical device to be reduced.

### SUMMARY

In view of this, an object of the disclosed technology is at least to provide a vertical semiconductor device capable of providing improved performance, a manufacturing method thereof, and an electronic device including the semiconductor device.

According to one aspect of the disclosed technology, there is provided a semiconductor device, including: a first device and a second device on the substrate, each of the first device and the second device comprising: a first source/drain layer, a channel layer, and a second source layer that are sequentially stacked, from bottom to top, on the substrate, and a gate stack around at least a part of an outer periphery of the channel layer, wherein sidewalls of the respective channel layers of the first device and the second device extend at least partially along different crystal planes or crystal plane families.

According to another aspect of the disclosed technology, there is provided a method of manufacturing a semiconductor device, including: providing, from bottom to top, a stack of a first source/drain layer, a channel layer, and a second source/drain layer on a substrate; defining an active region of a first device and an active region of a second device respectively from the stacked first source/drain layer, channel layer, and second source/drain layer, and extending sidewalls of the respective channel layers of the first device and the second device at least partially along different crystal planes or crystal plane families; and forming gate stacks each around at least a part of an outer periphery of the channel layer in the active region of a corresponding one of the first device and the second device.

According to another aspect of the disclosed technology, there is provided an electronic device including an integrated circuit formed at least partially by the above semiconductor device.

According to embodiments of the disclosed technology, the semiconductor device includes a vertical device, which may greatly reduce area and save space compared with the horizontal device. The gate stack is formed around at least a part of the outer periphery of the channel layer and a channel is formed in the channel layer, such that a gate length may be determined by a thickness of the channel layer, and the gate length can be better controlled. In addition, sidewalls of the respective channel layers of different devices may be arranged to extend at least partially along different crystal planes or crystal plane families. Since carriers may have different mobility in directions of different crystal planes or crystal plane families, the carrier mobility in the channel layers of different devices may be adjusted, and a conductive effect of different devices may be adjusted to optimize an overall performance of the semiconductor device.

### BRIEF DESCRIPTION OF THE DRAWINGS

Through the description described below with reference to the drawings of the embodiments of the disclosed technology, the above and other objectives, features, and advantages of the disclosed technology will be clearer.

FIGS. 1-18 show schematic diagrams of a process of manufacturing a semiconductor device according to an embodiment of the disclosed technology;

FIGS. 19-20 show schematic diagrams of certain stages in a process of manufacturing a semiconductor device according to another embodiment of the disclosed technology.

Throughout the drawings, the same or similar reference signs represent the same or similar components.

### DETAILED DESCRIPTION OF CERTAIN ILLUSTRATIVE EMBODIMENTS

Hereinafter, embodiments of the disclosed technology will be described with reference to the drawings. However, it should be understood that these descriptions are only exemplary and illustrative, and are not intended to limit the disclosed technology. In addition, in the following description, descriptions of well-known structures and technologies are omitted herein to avoid unnecessarily obscuring concepts of the disclosed technology.

The drawings show various structural schematic diagrams according to embodiments of the disclosed technology. The drawings are not drawn to scale, some details are enlarged and some details may be omitted for clarity of presentation. Shapes of the various regions and layers shown in the drawings and the relative size and positional relationship thereof are only exemplary. In practice, there may be deviations due to manufacturing tolerances or technical limitations. Regions/layers with different shapes, sizes, and relative positions may be designed by those ordinary skilled in the art as needed. In addition, singular forms are intended to include the plural forms as well, unless the context clearly indicates otherwise.

In the context of the disclosed technology, when a layer/element is referred to as being “on” another layer/element, the layer/element may be directly on the another layer/element, or there may be an intermediate layer/element there between. In addition, if a layer/element is located “on” another layer/element in one orientation, the layer/element may be located “under” the another layer/element when the orientation is reversed.

A semiconductor device according to an embodiment of the disclosed technology may include a plurality of vertical devices formed on a substrate. Each vertical device may include a first source/drain layer, a channel layer, and a second source/drain layer sequentially stacked on the substrate (e.g., from bottom to top). Layers may be adjacent to each other, and there may also be other semiconductor layers such as a leakage suppression layer and/or an on-state current enhancement layer (a semiconductor layer with a band gap larger or smaller than the adjacent layer) therebetween. A source/drain region of the device may be formed in the first source/drain layer and the second source/drain layer, and a channel region of the device may be formed in the channel layer. A space formed between the source/drain regions located at both ends of the channel region may form a conductive channel through the channel region. Active region stack configurations of different vertical devices may be the same or be different.

According to embodiments of the disclosed technology, the sidewalls of the channel layer of different devices, especially devices of different conductivity types, may extend at least partially along different crystal planes or crystal plane families. Since carriers may have different mobility in directions of different crystal planes or crystal plane families, the carrier mobility in the channel layers of different devices may be adjusted, and a conductive effect of different devices may be adjusted to optimize an overall performance of the semiconductor device. For example, in the case where the channel layer includes a single crystal semiconductor material or one of Si, SiGe or Ge crystals, at least a part of a sidewall of a channel layer of an n-type device may extend along a (100) crystal plane or a {100} crystal plane family, because the crystal plane or the crystal plane family is conducive to mobility of electrons; and at least part of a sidewall of a channel layer of a p-type device may extend along a (110) crystal plane or a {110} crystal plane family, because the crystal plane or the crystal plane family is conducive to mobility of holes. In addition, when devices are of different conductivity types, a complementary metal oxide semiconductor (CMOS) configuration may be formed.

According to the embodiments of the disclosed technology, not all sidewalls of the channel layer can be optimized (that is, allowing all of the sidewalls to extend along a desired crystal plane or crystal plane family), but only a part of the sidewalls can be optimized. For example, in order to improve device reliability and reduce process fluctuations, the channel layer may be chamfered. At this time, a rounded part of the sidewall may not extend along the desired crystal plane or crystal plane family. For another example, a sidewall with a larger area among the sidewalls of the channel layer may be optimized, and an influence of a sidewall with a smaller area may be ignored, for example, in the case of nanosheets. In this case, the crystal plane of the sidewall is not a single crystal plane family.

According to the embodiments of the disclosed technology, a direction from the first source/drain layer of the device toward the second source/drain layer of the device may be along a direction of a [100] crystal orientation or along a <100> crystal orientation family, which is parallel to a {100} crystal plane family and a {110} crystal plane family, that is, the {100} crystal plane family and {110} crystal plane family may be substantially perpendicular to the substrate, so that the sidewall of the channel layer extending along the {100} crystal plane family or {110} crystal plane family may be substantially perpendicular to the substrate.

When the sidewall of the channel layer extends along the crystal plane or crystal plane family, a sharp corner may be formed between adjacent sidewalls of the channel layer. Such a sharp corner is not stable, and may reduce the reliability of the device and cause fluctuations in device performances. To this end, the channel layer may be chamfered, so that the corner formed by the adjacent sidewalls of the channel layer may be a relatively gentle rounded corner.

The channel layer may be made of a single crystal semiconductor material to improve device performances, such as reducing channel resistance. The single crystal semiconductor material of the channel layers of different devices may have the same crystal orientation, and/or may have the same crystal structure. In this way, the channel layers of these devices may be manufactured with the same base, which is convenient to be manufactured and with fewer defects.

The first and second source/drain layers may, as an example, also be made of a single crystal semiconductor material. In this case, the single crystal semiconductor material of the channel layer and the single crystal semiconductor material of the source/drain layer may be eutectic. A mobility of the electrons or holes of a single crystal semiconductor material of the channel layer may be greater than a mobility of the electrons or holes of the first and second source/drain layers. In addition, a band gap of the first and second source/drain layers may be larger than a band gap of the single crystal semiconductor material of the channel layer.

The gate stack may be formed around at least a part of the outer periphery of the channel layer. Therefore, the gate length may be determined by a thickness of the channel layer itself, rather than being determined by etching time as in the conventional technology. The channel layer may for example be formed by epitaxial growth, so that its thickness may be well controlled. Therefore, the gate length may be well controlled.

The channel layers of different devices on the substrate may be substantially coplanar, for example, the channel layers may extend on a plane substantially parallel to the surface of the substrate. In one example, an upper surface and/or a lower surface of the channel layer of each device may be substantially coplanar with each other. Therefore, the channel layer of each device may have different thickness with each other, and accordingly may have different channel length.

The gate stack may be self-aligned to the channel layer. For example, the gate stack and the channel layer may be substantially coplanar. In one example, the channel layer may have an upper surface substantially coplanar with at least a part of an upper surface of the gate stack, and/or the channel layer may have a lower surface substantially coplanar with at least a part of a lower surface of the gate stack. For example, the outer periphery of the channel layer may be recessed inward with respect to outer peripheries of the first and second source/drain layers. In this way, the formed gate stack may be embedded in a recess of the channel layer recessed with respect to the first and second source/drain layers. A range of the gate stack in a stacking direction (a vertical direction, for example, substantially perpendicular to the substrate surface) of the first source/drain layer, the channel layer, and the second source/drain layer is within a range of the recess in the stacking direction. Therefore, an overlapping with the source/drain region can be reduced or even avoided, which helps to reduce a parasitic capacitance between the gate and the source/drain.

In the case where the first device and the second device are devices of different conductivity types (for example, the first device is an n-type device, and the second device is a p-type device), the gate stack, especially the gate conductor layer therein, may need to be formed differently for the first device and the second device (for example, gate conductor layers of the n-type device and the p-type device are formed by gate conductor materials with different work functions). For example, the first device and the second device may each include a corresponding gate conductor material with a suitable work function and self-aligned to a corresponding channel layer.

In addition, to facilitate the manufacturing of electrical contacts to the gate conductor layer, a gate contact pad for leading out the gate conductor layer may also be included. Such a gate contact pad may be in electrical contact with the gate stack (specifically, the gate conductor layer) and extend in a direction away from the channel layer (for example, extend beyond an outer periphery of the active region). Advantageously, to facilitate the manufacturing, such a gate contact pad may be formed by using the gate conductor layer of one of the first device and the second device (for example, the first device), this is so even for another device (for example, the second device). For example, the gate conductor layer of a device (for example, the first device) may extend externally from a corresponding recess to serve as a gate contact pad, and another portion of the gate conductor layer may extend to the gate conductor layer of another device (for example, the second device) to serve as a gate contact pad.

Each layer in the active region may be formed by epitaxial growth, so that its thickness may be precisely controlled. For example, the first source/drain layer may be a semiconductor layer epitaxially grown on the substrate, the channel layer may be a semiconductor layer epitaxially grown on the first source/drain layer, and the second source/drain layer may be a semiconductor layer epitaxially grown on the channel layer.

For example, such a semiconductor device may be manufactured as follows. Specifically, a stack of a first source/drain layer, a channel layer, and a second source/drain layer may be provided on the substrate from bottom to top. For example, the first source/drain layer may be provided by the substrate itself or by epitaxial growth on the substrate. Next, the channel layer may be epitaxially grown on the first source/drain layer, and the second source/drain layer may be epitaxially grown on the channel layer. During the epitaxial growth, a thickness of the grown channel layer may be controlled. Due to respective epitaxial growth, at least a pair of adjacent layers may have a clear crystal interface therebetween. In addition, each layer can be doped differently, so at least a pair of adjacent layers may have a doping concentration interface therebetween. For the channel layer, certain processing may be performed so that the channel layer may have different thicknesses in the first device region and the second device region. For example, after the channel layer is grown, a portion thereof in a certain device region may be thinned (for example, etched), or the channel layer may be further grown in a certain device region (that is, thickened); or, after the first source/drain layer is grown, a portion thereof in a certain device region is thinned (for example, etched), and then the channel layer is grown.

For the stacked first source/drain layer, channel layer, and second source/drain layer, the active region of the first device and the active region of the second device may be defined in the first device region and the second device region, respectively. For example, they may be selectively etched into desired shapes sequentially. The respective active regions of the first device and the second device may be obtained from the same first source/drain layer, channel layer, and second source/drain layer.

According to the embodiments of the disclosed technology, the sidewall of the channel layer may be formed along a certain crystal plane or crystal plane family. A same mask may be used when the active region is defined, so the sidewalls of the first source/drain layer and the second source/drain layer may also extend along the same crystal plane or crystal plane family. Thus, the active region may have a square column shape. In addition, for the first device and the second device, especially when they have different conductivity types, the sidewalls of the respective channel layers may extend at least partially along different crystal planes or crystal plane families.

To facilitate the connection of source/drain regions formed in the first source/drain layer in a subsequent process, etching of the first source/drain layer may only be performed to an upper portion of the first source/drain layer, so that a lower portion of the first source/drain layer may extend beyond an outer periphery of the upper portion. Then, gate stacks of corresponding devices are formed respectively around at least a part of the outer periphery of the channel layer in respective active regions of the first device and the second device.

In addition, the outer periphery of the channel layer may be recessed inward with respect to the outer peripheries of the first and second source/drain layers, so as to define a space for accommodating the gate stack. For example, this may be achieved by a selective etching. In this case, the gate stack may be embedded in the recess. To keep the sidewall of the channel layer extending along a corresponding crystal plane or crystal plane family, the recess of the channel layer may be achieved by isotropic etching.

To improve the reliability of the device, the sharp corner formed between the adjacent sidewalls of the channel layer may be gently rounded.

Source/drain regions may be formed in the first and second source/drain layers. For example, this may be achieved by doping the first and second source/drain layers. For example, ion implantation, plasma doping, etc. may be performed. According to a preferred embodiment, a sacrificial gate may be formed in a recess formed in an outer periphery of the channel layer recessed with respect to outer peripheries of the first and second source/drain layers, and then a dopant source layer is formed on the surfaces of the first and second source/drain layers, and dopants in the dopant source layer are enabled to enter into an active region via the first and second source/drain layers by, for example, annealing. The sacrificial gate may prevent the dopants in the dopant source layer from directly entering into the channel layer. However, a part of the dopants may still enter into ends of the channel layer close to the first source/drain layer and the second source/drain layer via the first and second source/drain layers. If the first device and the second device have different conductivity types, they may be doped separately.

Gate stacks for the corresponding devices may be formed respectively in recesses of the respective channel layers of the first device and the second device. If the first device and the second device have different conductivity types and form different gate stacks respectively, their gate stacks may be formed sequentially in time. When the gate stack is formed later, the gate conductor layer therein may be used to form respective gate contact pads of the first device and the second device. This may be formed by patterning the gate conductor layer.

The disclosed technology may be presented in various forms, some examples of which will be described below.

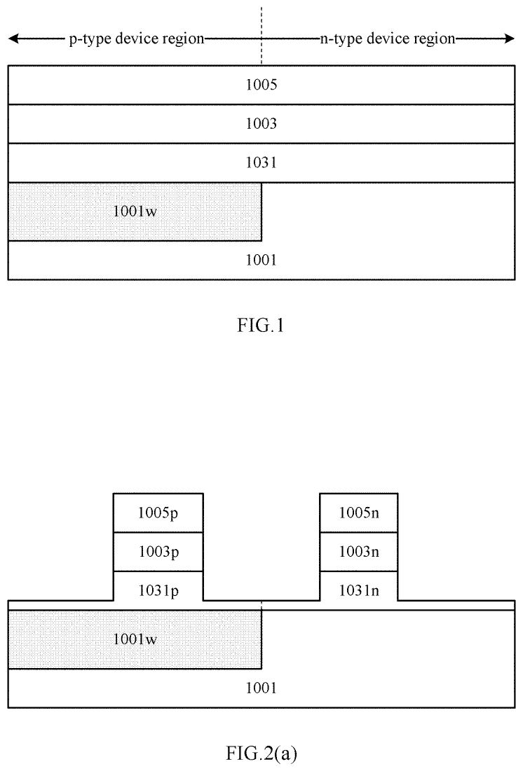

FIGS. 1-18 show schematic diagrams of a process of manufacturing a semiconductor device according to an embodiment of the disclosed technology. In the following, formations of an n-type device and a p-type device is described as an example, so as to show the formation of devices of different conductivity types in more detail. It should be understood that, devices of the same conductivity type may also be formed.

As shown in FIG. 1, a substrate 1001 is provided. The substrate 1001 may be a substrate in various forms, including but not limited to a substrate of bulk semiconductor material such as a bulk Si substrate, a semiconductor on insulator (SOI) substrate, a compound semiconductor substrate such as a SiGe substrate, and the like. In the following description, for convenience of description, a bulk Si substrate is described as an example. Here, a p-type silicon wafer is provided as the substrate 1001. In the substrate 1001, for example, an n-type well region 1001w may be formed by ion implantation. A p-type device may be formed on the n-type well region 1001w (hence, it is called a p-type device region); and a n-type device may be formed on another region (hence, it is called a n-type device region) of the p-type Si substrate 1001. According to the embodiments of the disclosed technology, the substrate 1001 may be a (100) single crystal silicon, a single crystal silicon germanium, or a single crystal germanium wafer. At this time, there are both crystal planes of a {100} crystal planes family and a {110} crystal plane family in crystal planes perpendicular to a (100) crystal plane, which is conducive to manufacturing of the following devices.

On the substrate 1001, a first source/drain layer 1031, a channel layer 1003, and a second source/drain layer 1005 may be sequentially formed by, for example, epitaxial growth. For example, the first source/drain layer 1031 may include SiGe (an atomic percentage of Ge may be about 10-40%) with a thickness of about 20-50 nm; the channel layer 1003 may include Si with a thickness of about 10-100 nm; the second source/drain layer 1005 may include SiGe (an atomic percentage of Ge may be about 10-40%) with a thickness of about 20-50 nm. The materials selected for the first source/drain layer 1031, the channel layer 1003, and the second source/drain layer 1005 is not limited thereto, and may include other semiconductor materials that may provide an appropriate etching selectivity. For example, the channel layer 1003 may include Si:C, Ge, or III-V group compound semiconductor materials. In addition, the channel layer 1003 may include semiconductor materials with the same constituent components as the first source/drain layer 1031 and the second source/drain layer 1005, but with different component contents (for example, with the same material SiGe, but their atomic percentages of Ge are different), as long as the channel layer 1031 has an etching selectivity with respect to the first source/drain layer 1031 above it and the second source/drain layer 1005 above it.

Next, active regions of the device may be defined. For example, this can be done as follows. Specifically, as shown in FIGS. 2(a) and 2(b) (FIG. 2(a) is a cross-sectional view, FIG. 2(b) is a top view, where line AA′ shows an interception position of the cross section), a photoresist (not shown) may be formed on the second source/drain layer 1005 shown in FIG. 1, and the photoresist is patterned into a desired shape by photolithography (exposure and development). Here, the photoresist may be patterned according to the direction of the crystal plane or the crystal plane family. For example, for the p-type device on the left side, it is expected that the channel sidewall extends along a (110) crystal plane or a {110} crystal plane family, so the corresponding photoresist may be patterned into a substantially rectangular pattern with the sidewall parallel to a (110) crystal plane or a {110} crystal plane family of the substrate 1001 (because the channel layer is epitaxially grown on the substrate 1001, thus the sidewall is also parallel to a (110) crystal plane or a {110} crystal plane family of the channel layer). Similarly, for the n-type device on the right side, it is expected that the channel sidewall extends along a (100) crystal plane or a {100} crystal plane family, so the corresponding photoresist may be patterned into a substantially rectangular pattern with the sidewall parallel to a (110) crystal plane or {110} crystal plane family of the substrate 1001 (because the channel layer is epitaxially grown on the substrate 1001, thus the sidewall is also parallel to a (100) crystal plane or a {100} crystal plane family of the channel layer). Then, the second source/drain layer 1005, the channel layer 1003 and the first source/drain layer 1031 are sequentially subjected to selective etching such as reactive ion etching (RIE) by using the patterned photoresist as a mask. The etching proceeds to the first source/drain layer 1031, but not to a bottom surface of the first source/drain layer 1031, so as to facilitate subsequent manufacturing of contacts. Thus, after the etching, square columns are formed on upper portions of the second source/drain layer 1005, the channel layer 1003, and the first source/drain layer 1031. RIE, for example, may be performed in a direction substantially perpendicular to the surface of the substrate, so that two square columns are also substantially perpendicular to the surface of the substrate. Then, the photoresist may be removed.

In this example, active regions for the p-type device and the n-type device are patterned in the p-type device region and the n-type device region, respectively. Here, for the convenience of description, the first source/drain layer, channel layer, and second source/drain layer for the p-type device are illustrated as 1031p, 1003p, and 1005p respectively, and the first source/drain layer, channel layer, and second source/drain layer for the n-type device are illustrated as 1031n, 1003n, and 1005n respectively. At this stage, the first source/drain layer 1031 is still continuous between the p-type device and the n-type device regions. FIG. 2(a) schematically shows a boundary between the p-type device region and the n-type device region with a dotted line. In the following description, when the p-type device region and the n-type device region are described collectively, reference signs 1031, 1003, and 1005 are used; and when the p-type device region and the n-type device region need to be described separately, reference signs 1031p, 1003p, and 1005p, and 1031n, 1003n, and 1005n are used respectively.

As shown in FIGS. 2(a) and 2(b), after the etching, the sidewalls of the respective second source/drain layer 1005p, channel layer 1003p, and first source/drain layer 1031p in the p-type device region extend at least partially along a (110) crystal plane or {110} crystal plane family, and the sidewalls of the respective second source/drain layer 1005n, channel layer 1003n, and first source/drain layer 1031n in the n-type device region extend at least partially along a (100) crystal plane or a {100} crystal plane family.

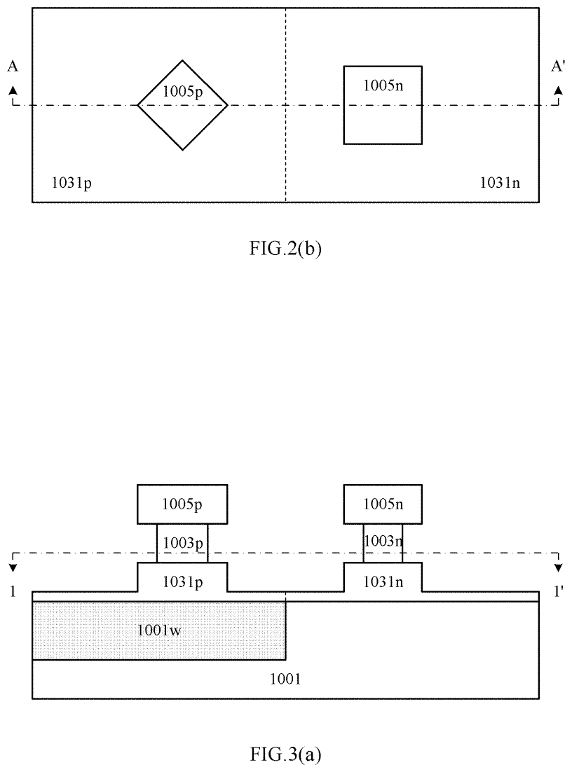

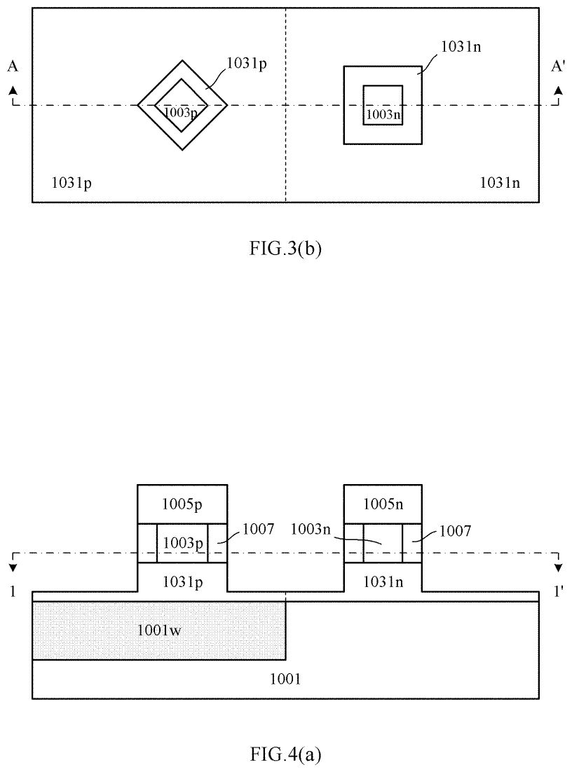

Then, as shown in FIGS. 3(a) and 3(b) (wherein FIG. 3(a) is a front cross-sectional view, FIG. 3(b) is a top cross-sectional view, where line 11′ shows an interception position of the top cross section, and line AA′ shows an interception position of the front cross section), an outer periphery of the channel layer 1003 may be recessed with respect to outer peripheries of the first source/drain layer 1031 and the second source/drain layer 1005 (in this example, recessed along a lateral direction substantially parallel to the surface of the substrate). The recessed upper and lower sidewalls are defined by interfaces between the channel layer 1003 and the second source/drain layer 1005 and between the channel layer 1003 and the first source/drain layer 1031, respectively. For example, this may be achieved by further isotropically and selectively etching (such as, wet etching using TMAH solution) the channel layer 1003 with respect to the first source/drain layer 1031 and the second source/drain layer 1005. For example, atomic layer etching (ALE) or digital etching may be used to perform the selective etching so as to control an amount of etching more accurately.

In this way, active regions (the etched first source/drain layer 1031, channel layer 1003 and second source/drain layer 1005) of the devices are respectively defined. In this example, each of the active regions of the devices has a substantially square column shape. In the active region of the p-type device, an upper portion of the first source/drain layer 1031p and an outer periphery of the second source/drain layer 1005p are substantially aligned with each other, while an outer periphery of the channel layer 1003p is relatively recessed. As shown in FIG. 3(b), due to isotropic etching, the channel layer 1003p basically remains conformal before and after the etching, and thus has a square column shape with a smaller lateral size, and the sidewall remains to extend at least partially along a (110) crystal plane or {110} crystal plane family. In the active region of the n-type device, an upper portion of the first source/drain layer 1031n and an outer periphery of the second source/drain layer 1005n are substantially aligned with each other, while an outer periphery of the channel layer 1003n is relatively recessed. As shown in FIG. 3(b), due to the isotropic etching, the channel layer 1003n basically remains conformal before and after the etching, and thus has a square column shape with a smaller lateral size, and the sidewall remains to extend at least partially along a (100) crystal plane or a {100} crystal plane family. The upper and lower sidewalls of each of the recesses are defined by the interfaces between the channel layer 1003 and the semi-second source/drain layer 1005 and between the channel layer 1003 and the first source/drain layer 1031, respectively.

As shown in FIG. 3(b), the sidewall of the channel layer 1003p extends along a (110) crystal plane or the {110} crystal plane family, so that a sharp corner is formed between adjacent sidewalls. Similarly, the sidewall of the channel layer 1003n extends along a (100) crystal plane or a {100} crystal plane family, so that a sharp corner is formed between adjacent sidewalls. Such sharp corners may be damaged in subsequent processes, resulting in process instability, degradation of device reliability, and fluctuations in device performances. To this end, the sharp corners may be chamfered to become rounded. For example, such sharp corners may be rounded by oxidation (and the oxide layer is removed subsequently), as shown in FIG. 4(b).

In the recess formed by the channel layer 1003 recessed with respect to the upper portion of the first source/drain layer 1031 and the outer periphery of the second source/drain layer 1005, a gate stack will be formed subsequently. To prevent the subsequent processing from affecting the channel layer 1003 or leaving unnecessary material in the recess and thus affecting the formation of the subsequent gate stack, a material layer may be filled in the recess to occupy the space of the gate stack (therefore, this material layer may be called as “sacrificial gate”). For example, this may be achieved by depositing nitride on the structure shown in FIGS. 3(a) and 3(b), and then etching back, such as RIE, on the deposited nitride. The RIE may be performed in a direction substantially perpendicular to the surface of the substrate, and the nitride may be left only in the recess to form a sacrificial gate 1007, as shown in FIGS. 4(a) and 4(b) (wherein FIG. 4(a) is a front cross-sectional view, FIG. 4(b) is a top cross-sectional view, where line 11′ shows an interception position of the top cross section, line AA′ shows an interception position of the front cross section). In this case, the sacrificial gate 1007 may substantially fill the above recess.

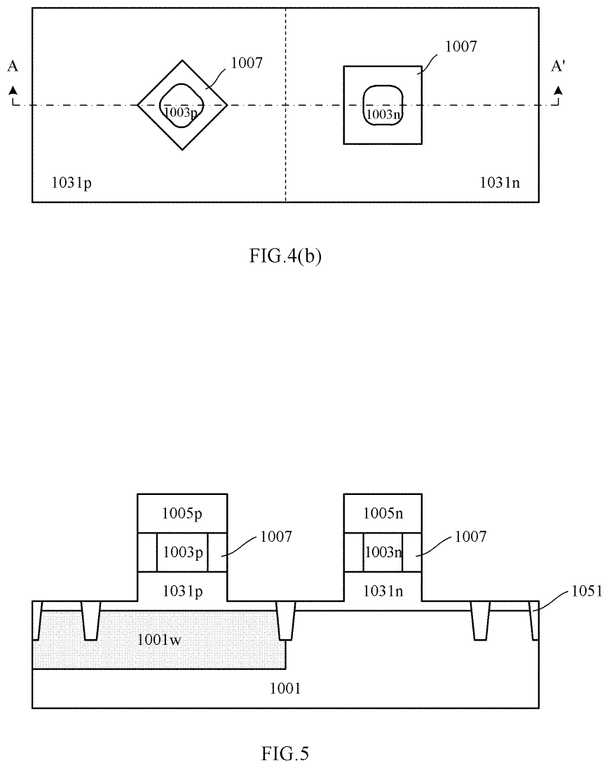

In addition, a shallow trench isolation (STI) may also be formed. For example, the STI 1051 may be formed by etching a trench where isolation is required, and then filling the trench with oxide, as shown in FIG. 5. Those ordinary skilled in the art know a variety of STI processes, which will not be repeated here. The STI 1051 may be arranged around the active region of the p-type device and around the active region of the n-type device, respectively.

Next, source/drain regions may be formed in the first source/drain layer 1031 and the second source/drain layer 1005. This may be formed by doping the first source/drain layer 1031 and the second source/drain layer 1005. For example, this may be done as follows.

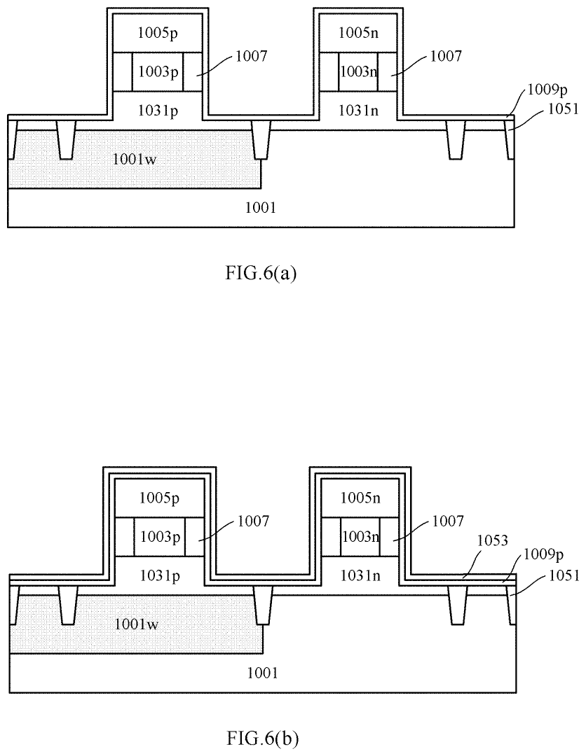

Specifically, as shown in FIG. 6(a), a p-type dopant source layer 1009p may be formed on the structure shown in FIG. 5. For example, the p-type dopant source layer 1009p may include an oxide such as silicon oxide, which contains a p-type dopant such as B. Here, the dopant source layer 1009p may be a thin film, for example, with a thickness of about 2-10 nm, so that it may be substantially conformally deposited on the surface of the structure as shown in FIG. 5 by, for example, chemical vapor deposition (CVD) or atomic layer deposition (ALD).

In addition, optionally, in order to avoid cross-contamination with the subsequently formed n-type dopant source layer, a diffusion barrier layer 1053 may be further formed on the p-type dopant source layer 1009p, as shown in FIG. 6(b). For example, the diffusion barrier layer 1053 may include nitride, oxynitride, oxide, etc., with a thickness of about 0.5-5 nm.

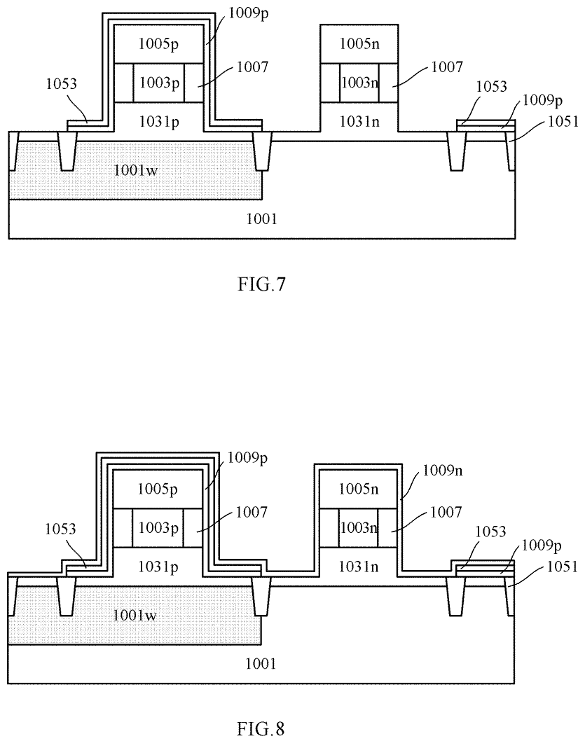

Then, as shown in FIG. 7, the p-type dopant source layer 1009p (and the diffusion barrier layer 1053) may be patterned (for example, by photolithography) to be left in a region where a p-type doping is required. In this example, the p-type dopant source layer 1009p may be left in a p-type device region (because its source/drain layer needs to be p-type doped) and a region in the n-type device region where a body contact will be formed (if any, because a p-type body contact region may be formed for a n-type device).

Next, as shown in FIG. 8, an n-type dopant source layer 1009n may be formed on the structure shown in FIG. 7. For example, the n-type dopant source layer 1009n may include oxide, which contains n-type dopants such as As or P, with a thickness of about 2-10 nm. The n-type dopant source layer 1009n may be formed in the same manner as the p-type dopant source layer 1009p. The n-type dopant source layer 1009n may cover a region that requires n-type doping, such as an n-type device region (because its source/drain layer needs to be n-type doped) and a region in the p-type device region where a body contact will be formed (if any, because an n-type body contact region may be formed for a p-type device).

Alternatively, another diffusion barrier layer (not shown in the figure) may be formed on the n-type dopant source layer 1009n to suppress out-diffusion or cross-contamination.

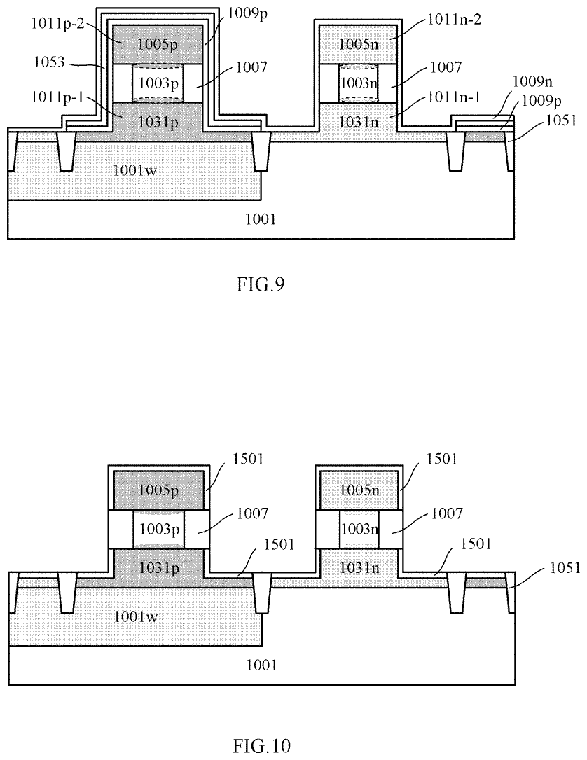

Next, as shown in FIG. 9, dopants contained in the dopant source layers 1009p and 1009n may be brought into the active region by annealing at about 800-1100° C., for example, thereby forming a doped region therein, as shown in the shaded part in the figure. More specifically, in the p-type device region, one of source/drain regions 1011p-1 of the p-type device may be formed in the first source/drain layer 1031p, and another source/drain region 1011p-2 of the p-type device may be formed in the second source/drain layer 1005p. Similarly, in the n-type device region, one of source/drain regions 1011n-1 of the n-type device may be formed in the first source/drain layer 1031n, and another source/drain region 1011p-2 of the n-type device may be formed in the second source/drain layer 1005n. Afterwards, the dopant source layers 1009p and 1009n and the diffusion barrier layer 1053 may be removed.

Despite the presence of the sacrificial gate 1007, the dopants may also enter into the channel layer 1003 via the first source/drain layer 1031 and the second source/drain layer 1005, thereby forming a certain doping distribution (for example, forming an extension region) at upper and lower ends of the channel layer 1003, as shown by an elliptical dashed circle in the figure. This doping distribution may reduce a resistance between the source/drain region and the channel when the device is turned on, thereby improving the device performances.

In the above example, source/drain regions are formed by driving dopants from the dopant source layers in the active region, but the disclosed technology is not limited thereto. For example, the source/drain regions may be formed by ion implantation, plasma doping (for example, conformal doping along the surface of the structure in FIG. 5), etc. Of course, this can be carried out separately for the region that requires p-type doping and the region that requires n-type doping. When one region is processed, a photoresist, for example, may be used to block another region. Such a sub-regional processing is common in CMOS processes. In addition, if devices of the same conductivity type are formed, in-situ doping may also be performed when the source/drain layers are grown.

In the above example, the p-type dopant source layer 1009p is formed first, and then the n-type dopant source layer 1009n is formed. However, the disclosed technology is not limited thereto, and the forming order may be exchanged.

Further, to reduce contact resistance, the source/drain layers may also be silicidated. For example, a layer of NiPt (for example, with a Pt content of about 2-10% and a thickness of about 2-10 nm) may be deposited on the structure (with the dopant source layer and diffusion barrier layer removed) shown in FIG. 9, and annealed at a temperature of about 200-400° C., so that NiPt reacts with Si to form SiNiPt. Afterwards, the unreacted remaining NiPt may be removed to form a silicide 1501 on the surface of the source/drain layer, as shown in FIG. 10. In this example, the silicide 1501 is also formed on a horizontal surface of the lower portion (a portion that is not etched) of the first source/drain layer 1031.

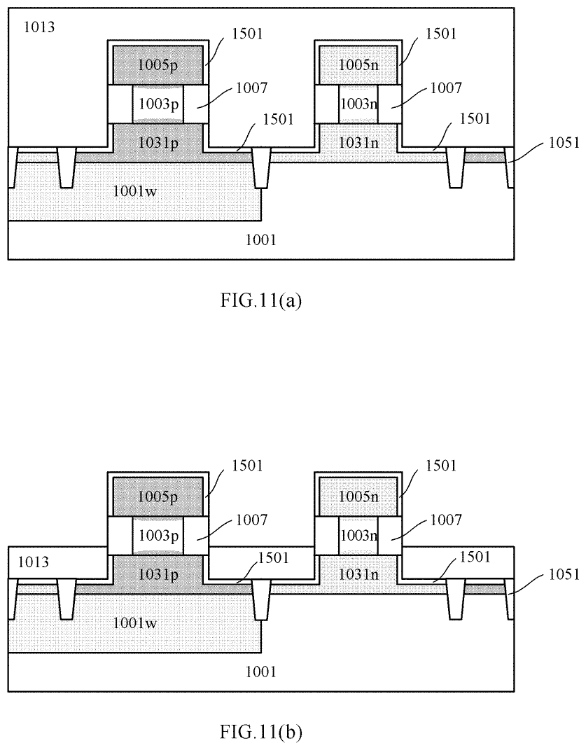

Next, a gate stack may be formed. To reduce an overlapping between the gate stack and the source/drain layer, a dielectric layer may be formed around the active region to block the underlying source/drain layer 1031. For example, as shown in FIGS. 11(a) and 11(b), an oxide may be deposited on the structure shown in FIG. 10 and etched back to form a dielectric layer 1013, which serves as a first isolation layer. Before the etching back, the deposited oxide may be planarized, such as by chemical mechanical polishing (CMP) or sputtering. Here, a top surface of the dielectric layer 1013 may be located between a top surface and a bottom surface of the channel layer 1003, which helps to form a self-aligned gate stack. This will be described in further detail below.

When forming the first isolation layer, the sacrificial gate 1007 may be reserved to prevent the material of the first isolation layer from entering into a recess, for accommodating gate stacks, of the channel layer 1003 recessed with respect to the first source/drain layer 1031 and the second source/drain layer 1005. Afterwards, the sacrificial gate 1007 may be removed to release a space of the channel layer 1003 recessed with respect to the first source/drain layer 1031 and the second source/drain layer 1005. For example, the sacrificial gate 1007 (nitride) may be selectively etched with respect to the dielectric layer 1013 (oxide) and the first source/drain layer 1031, the second source/drain layer 1005 (SiGe) and the channel layer 1003 (Si).

Then, gate stacks may be formed in the recess. Here, different gate stacks may be formed for the p-type device and n-type device. Hereinafter, forming a gate stack of the p-type device first is described as an example. However, the disclosed technology is not limited thereto. For example, a gate stack of the n-type device may be formed first.

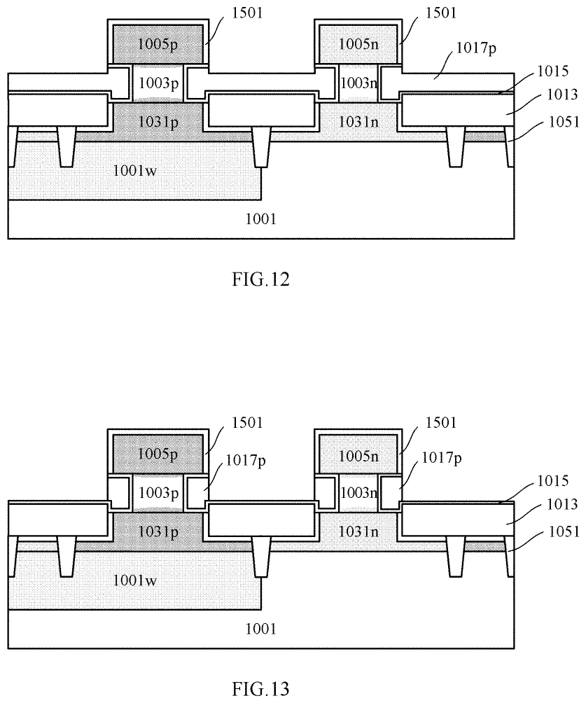

Specifically, as shown in FIG. 12, a gate dielectric layer 1015 and a gate conductor layer 1017p for the p-type device may be sequentially deposited on the structure shown in FIG. 11(b) (with the sacrificial gate 1007 removed), and the deposited gate conductor layer 1017p (and optionally the gate dielectric layer 1015) is etched back such that a top surface of a portion of the layer 1017p outside the recess is not higher, preferably lower, than a top surface of the channel layer 1003. For example, the gate dielectric layer 1015 may include a high-K gate dielectric such as HfO2; the gate conductor layer 1017p may include a metal gate conductor. In addition, a function adjusting layer may also be formed between the gate dielectric layer 1015 and the gate conductor layer 1017p. Before forming the gate dielectric layer 1015, an interface layer such as oxide may also be formed.

Due to an arrangement of the top surface of the dielectric layer 1013, the gate stack only overlaps a side surface of the channel layer 1003 in a vertical direction, and does not overlap side surfaces of the first and second source/drain layers in the vertical direction. That is, the gate stack is self-aligned with the channel layer 1003. In this way, the gate stack may be embedded in the recess so as to overlap an entire height of the channel layer 1003.

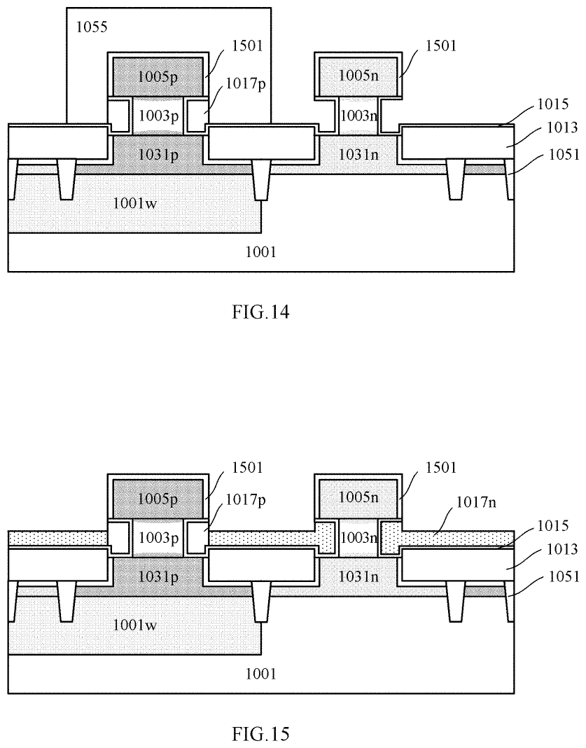

Then, as shown in FIG. 13, the gate conductor layer 1017p may be selectively etched such as RIE. The active region, especially the second source/drain layer at the top, may be used as a mask for etching. For example, the RIE may be performed in a direction substantially perpendicular to the surface of the substrate, so the gate conductor layer 1017p may be only remained in the recess. The etching may stop at the gate dielectric layer 1015. Then, as shown in FIG. 14, the gate conductor layer 1017p (which is currently in the recess) in the p-type device region may be masked with, for example, a photoresist 1055, and the gate conductor layer 1017p in the n-type device region may be exposed. Afterwards, the gate conductor layer 1017p in the n-type device region may be removed by selective etching such as wet etching. Thus, a gate stack (1015/1017p) for the p-type device is formed, and the gate stack is embedded in the recess of the channel layer 1003p of the p-type device.

Next, a gate stack for the n-type device may be formed. The gate stack of n-type devices may also be similarly formed. For example, as shown in FIG. 15, a gate conductor layer 1017n for the n-type device may be formed. For example, the gate conductor layer 1017n may be deposited on the structure shown in FIG. 14 (with the photoresist 1055 removed), and the deposited gate conductor layer 1017n may be etched back such that the top surface of the portion of the layer 1017n outside the recess is not higher, preferably lower, than the top surface of the channel layer 1003. For example, the gate conductor layer 1017n may include a metal gate conductor. In addition, a function adjusting layer may also be formed between the gate dielectric layer 1015 and the gate conductor layer 1017n. In this example, the n-type device and the p-type device may share the same gate dielectric layer 1015; of course, the disclosed technology is not limited thereto. For example, the gate dielectric layer 1015 may also be removed, and another gate dielectric layer may be formed for the n-type device. Since the n-type device channel layer 1003n and the p-type device channel layer 1003p are simultaneously formed by film growth and the selective etching, the n-type device channel layer 1003n has an upper surface substantially coplanar with the upper surface of the p-type device channel layer 1003p, and the bottom surface of the n-type device channel layer 1003n is substantially coplanar with the bottom surface of the p-type device channel layer 1003p.

It can be seen that the gate conductor layer 1017n is formed not only in the n-type device region but also in the p-type device region, and is in contact with the gate conductor layer 1017p. Afterwards, a gate contact pad may be formed by using the gate conductor layer 1017n, so as to subsequently form a contact to the gate.

Of course, a manner of forming the gate stack is not limited thereto. For example, after forming the gate stack for the p-type device, the p-type device region may be masked with a photoresist, and a portion of the gate conductor layer 1017p in the n-type device region may be removed by a selective etching such as RIE. And then, a gate stack for the n-type device may be formed in the n-type device region (for example, in the case where the photoresist is left to mask the p-type device region).

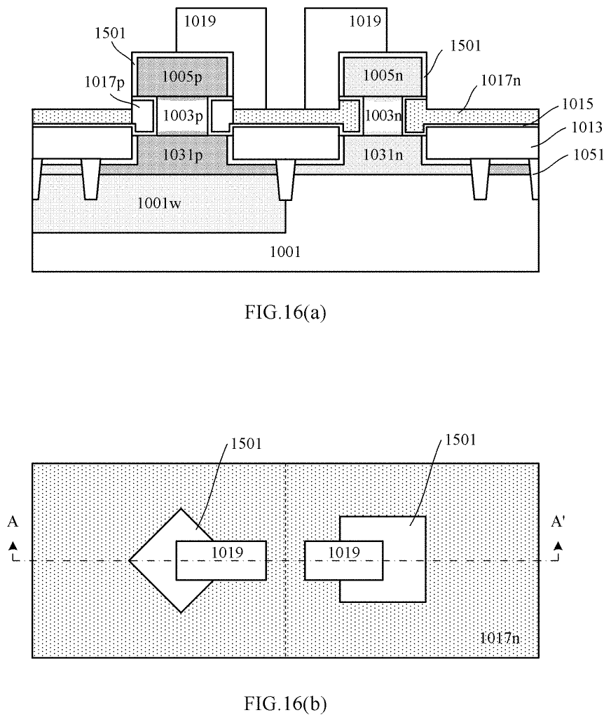

Next, the gate conductor layer 1017n may be patterned to form a gate contact pad, so as to facilitate subsequent interconnection production. For example, as shown in FIGS. 16(a) and 16(b) (wherein FIG. 16(a) is a cross-sectional view, FIG. 16(b) is a top view, where line AA′ shows an interception position of the cross section), a photoresist 1019 may be formed on the structure shown in FIG. 15. The photoresist 1019 is patterned, for example, by photolithography to cover a portion of the gate conductor layer 1017n exposed outside the recess, and other portions of the gate conductor layer 1017n exposed outside the recess are exposed. In this example, as shown in FIG. 16(b), the photoresist 1019 may, in the p-type device region and the n-type device region, have a stripe shape extending in a certain direction from an outer periphery of the corresponding active region, respectively. In order for patterning, photoresist strips on the p-type device region and the n-type device region are substantially aligned with each other.

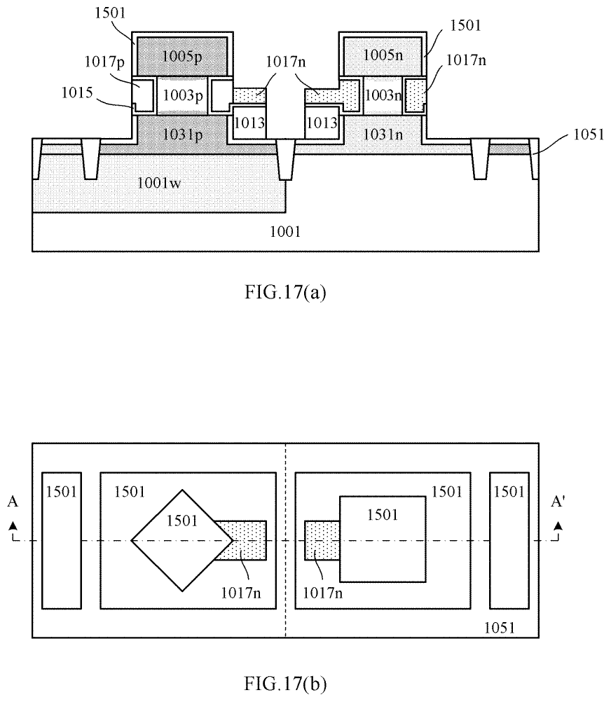

Then, as shown in FIGS. 17(a) and 17(b) (wherein FIG. 17(a) is a cross-sectional view, FIG. 17(b) is a top view, where line AA′ shows an interception of the cross section), the photoresist 1019 may be used as a mask to selectively etch, such as RIE, the gate conductor layer 1017n. In this way, for the gate conductor layer 1017n, a portion blocked by the photoresist 1019, in addition to a portion left in the recess, is retained and used as a gate contact pad. Subsequently, an electrical connection to the gate stack may be achieved through the gate contact pad.

In this example, as shown in FIG. 17(b), the sidewall of the channel layer of the p-type device at least partially extends along a (110) crystal plane or the {110} crystal plane family, and the sidewall of the channel layer of the n-type device at least partially extends along a (100) crystal plane or a {100} crystal plane family. The gate conductor layer 1017n may, in the p-type device region and the n-type device region, have a stripe shape extending in a certain direction from an outer periphery of the corresponding active region, respectively.

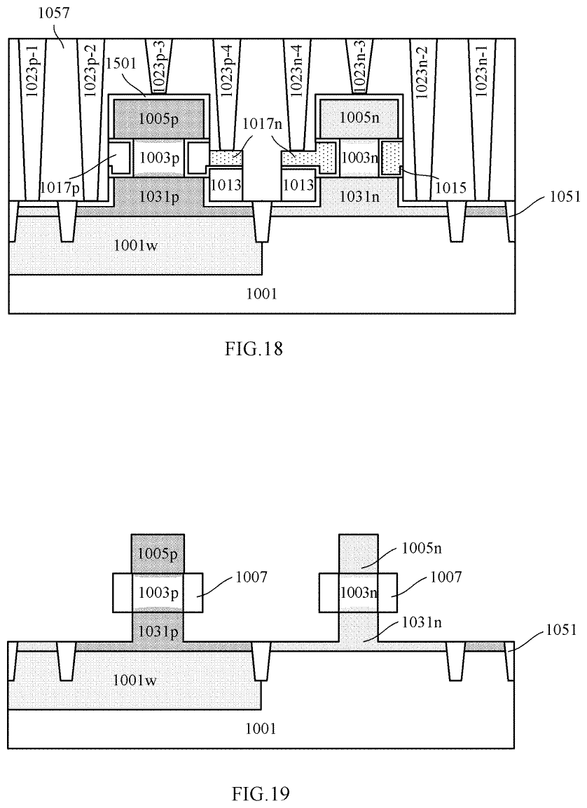

Then, as shown in FIG. 18, an interlayer dielectric layer 1057 may be formed on the structure shown in FIGS. 17(a) and 17(b). For example, an oxide may be deposited and planarized, such as CMP, to form the interlayer dielectric layer 1057. In the interlayer dielectric layer 1057, electrical contacts 1023p-1 to 1023p-4 may be formed to a n-type well region, a source/drain region of the p-type device and the gate conductor layer, and electrical contacts 1023n-1 to 1023n-4 may be formed to a p-type substrate, a source/drain region of the n-type device and the gate conductor layer. These contacts may be formed by etching holes in the interlayer dielectric layer 1057 and filling the holes with conductive materials such as a metal (for example, tungsten). Before filling with the metal, a barrier layer such as TiN may be formed on inner walls of the contact holes.

The semiconductor device according to this embodiment may include a p-type device and an n-type device in a form of vertical devices. Each of the p-type device and the n-type device includes a first source/drain layer 1031, a channel layer 1003, and a second source/drain layer 1005 stacked in a vertical direction. Source/drain regions are formed in the first source/drain layer 1031 and the second source/drain layer 1005. The channel layer 1003 is recessed laterally, and the gate stack is formed around an outer periphery of the channel layer 1003 and is embedded in the recess. The sidewalls of the channel layers 1003p and 1003n of the p-type device and the n-type device extend along different crystal planes. Each device further includes a gate contact pad extending externally from the gate conductor.

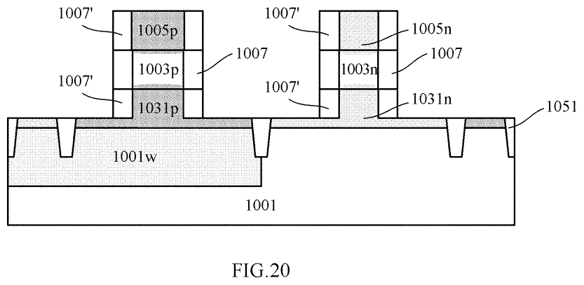

FIGS. 19 to 20 show schematic diagrams of certain stages in a process of manufacturing a semiconductor device according to another embodiment of the disclosed technology.

To reduce an overlapping capacitance between the source/drain and the gate by reducing a facing area between the source/drain and the gate, the source/drain layer may also be refined. For example, as shown in FIG. 19, in the structure shown in FIG. 9 (with the dopant source layer and diffusion barrier layer removed), the source/drain layer may be selectively etched to reduce its lateral size (even smaller than the channel layer). Alternatively, to reduce a contact resistance, the refined source/drain layer may be subjected to silicidation process such that a silicide may be formed on the surface of the source/drain layer. The silicidation process has been described above in conjunction with FIG. 10, and will not be repeated here. Afterwards, as shown in FIG. 20, a shielding layer 1007′ may be formed on sidewalls of the second source/drain layer 1005 and the first source/drain layer 1031 that are recessed with respect to the sacrificial gate 1007. Sidewalls of the shielding layer 1007′ are substantially coplanar with sidewalls of the sacrificial gate 1007. For example, a low-k dielectric may be used to form a low-k dielectric spacer 1007′ through a spacer forming process. In the subsequent processes, a gate stack is formed in a recess formed by the channel layer 1003 recessed with respect to the spacer 1007′.

Next, processes of forming gate stacks in the recess of the channel layer 1003 with respect to the shielding layer 1007′, forming gate contact pads, and forming respective electrical contacts of the two devices may be performed as described above in conjunction with FIGS. 10 to 18, and will not repeated here.

The semiconductor device according to the embodiment of the disclosed technology may be applied to various electronic devices. For example, by integrating a plurality of the semiconductor devices and other devices (for example, other forms of transistors, etc.), it is possible to form an integrated circuit (IC) and thereby construct an electronic device. Therefore, the disclosed technology also provides an electronic device including the above semiconductor device. The electronic device may also include components such as a display screen adapted to an integrated circuit and a wireless transceiver adapted to an integrated circuit. Such an electronic device includes a smart phone, computer, tablet computer (PC), artificial intelligence, wearable device, mobile power supply, and so on.

According to an embodiment of the disclosed technology, a manufacturing method of a system on chip (SoC) is further provided. This method may include the above described method of manufacturing a semiconductor device. Specifically, a variety of devices may be integrated on the chip, at least some of which are manufactured according to the method of the disclosed technology.

In the above description, technical details such as patterning and etching of each layer have not been described in detail. However, those ordinary skilled in the art should understand that layers, regions, etc. of desired shapes may be formed by using various technical means. In addition, to form the same structure, those ordinary skilled in the art can also design a method that is not completely the same as the method described above. In addition, although the embodiments are described above separately, this does not mean that means in the embodiments cannot be advantageously used in combination with each other.

The embodiments of the disclosed technology have been described above. However, these embodiments are used for illustrative purposes only, and are not used to limit the protection scope of the disclosed technology. The protection scope of the disclosed technology is defined by the claims and equivalent substitutions thereof. Those ordinary skilled in the art may make various substitutions and modifications, and such modifications and modifications should also be regarded as falling within the protection scope of the disclosed technology.

1. A semiconductor device, comprising:
a substrate; and
a first device and a second device on the substrate, each of the first device and the second device comprising:
a first source/drain layer, a channel layer, and a second source layer that are sequentially stacked, from bottom to top, on the substrate, and a gate stack around at least a part of an outer periphery of the channel layer,
wherein sidewalls of the respective channel layers of the first device and the second device extend at least partially along different crystal planes or crystal plane families.

2. The semiconductor device according to claim 1, wherein,
the channel layer of the first device comprises a single crystal semiconductor material; and/or
the channel layer of the second device comprises a single crystal semiconductor material.

3. The semiconductor device according to claim 2, wherein,
the first device is an n-type device, and at least a part of the sidewall of the channel layer of the first device extends along a (100) crystal plane or a {100} crystal plane family, wherein the second device is a p-type device, and wherein at least a part of the sidewall of the channel layer of the second device extends along a (110) crystal plane or a {110} crystal plane family; or
the first device is a p-type device, and at least a part of the sidewall of the channel layer of the first device extends along a (110) crystal plane or a {110} crystal plane family, wherein the second device is an n-type device, and wherein at least a part of the sidewall of the channel layer of the second device extends along a (100) crystal plane or a {100} crystal plane family.

4. The semiconductor device according to claim 1, wherein,
the first device is an n-type device, the channel layer of the first device comprises a semiconductor material of one of Si, SiGe, or Ge crystals, and at least a part of the sidewall of the channel layer extends along a (100) crystal plane or a {100} crystal plane family, wherein the second device is a p-type device, the channel layer of the second device comprises a semiconductor material of one of Si, SiGe, or Ge crystals, and wherein at least a part of the sidewall of the channel layer extends along a (110) crystal plane or a {110} crystal plane family; or the first device is a p-type device, the channel layer of the first device comprises a semiconductor material of one of Si, SiGe, or Ge crystals, and at least a part of the sidewall of the channel layer extends along a (100) crystal plane or a {110} crystal plane family, wherein the second device is an n-type device, the channel layer of the second device comprises a semiconductor material of one of Si, SiGe, or Ge crystals, and wherein at least a part of the sidewall of the channel layer extends along a (100) crystal plane or a {100} crystal plane family.

5. The semiconductor device according to claim 4, wherein a direction from the first source/drain layer toward the second source/drain layer of the first device is along a [100] crystal orientation or along a <100> crystal orientation family, and/or wherein a direction from the first source/drain layer toward the second source/drain layer of the second device is along the [100] crystal orientation or along the <100> crystal orientation family.

6. The semiconductor device according to claim 1, wherein,
the channel layer of the first device comprises a single crystal semiconductor material and the channel layer of the second device comprises a single crystal semiconductor material, and the channel layer of the first device has a crystal orientation the same as that of the channel layer of the second device.

7. The semiconductor device according to claim 1, wherein,
the channel layer of the first device comprises a single crystal semiconductor material and the channel layer of the second device comprises a single crystal semiconductor material, and the channel layer of the first device has a crystal structure the same as that of the channel layer of the second device.

8. The semiconductor device according to claim 1, wherein:
a corner formed by adjacent sidewalls of the channel layer of the first device is a rounded corner; and/or
a corner formed by adjacent sidewalls of the channel layer of the second device is a rounded corner.

9. The semiconductor device according to claim 1, wherein the outer periphery of the channel layer is recessed inward with respect to outer peripheries of the first and second source/drain layers.

10. The semiconductor device according to claim 1, wherein the channel layer of the first device has an upper surface substantially coplanar with an upper surface of the channel layer of the second device, and/or wherein the channel layer of the first device has a lower surface substantially coplanar with a lower surface of the channel layer of the second device.

11. The semiconductor device according to claim 1, wherein each of the first device and the second device further comprises:
a gate contact pad extending laterally from a gate conductor layer of the gate stack in a direction away from the channel layer, wherein the gate conductor layer and the corresponding gate contact pad of at least one of the first device or the second device comprise different materials.

12. The semiconductor device of claim 11, wherein the gate contact pads of the first device and the second device comprise the same material.

13. The semiconductor device according to claim 12, wherein the gate conductor layer and the corresponding gate contact pad of either one of the first device or the second device comprise the same material, and extend integrally.

14. The semiconductor device according to claim 1, wherein the channel layer of the first device has an upper surface substantially coplanar with at least a part of an upper surface of the gate stack of the first device, and has a lower surface substantially coplanar with at least a part of a lower surface of the gate stack of the first device, and/or wherein the channel layer of the second device has an upper surface substantially coplanar with at least a part of an upper surface of the gate stack of the second device, and has a lower surface substantially coplanar with at least a part of a lower surface of the gate stack of the second device.

15. A method of manufacturing a semiconductor device, comprising:
providing, from bottom to top, a stack of a first source/drain layer, a channel layer, and a second source/drain layer on a substrate;
defining an active region of a first device and an active region of a second device respectively from the stacked first source/drain layer, channel layer, and second source/drain layer, and extending sidewalls of the respective channel layers of the first device and the second device at least partially along different crystal planes or crystal plane families; and
forming gate stacks each around at least a part of an outer periphery of the channel layer in the active region of a corresponding one of the first device and the second device.

16. The method according to claim 15, wherein,
the channel layer of the first device comprises a single crystal semiconductor material; and/or the channel layer of the second device comprises a single crystal semiconductor material.

17. The method according to claim 16, wherein,
the first device is an n-type device, and at least a part of the sidewall of the channel layer of the first device extends along a (100) crystal plane or a {100} crystal plane family, wherein the second device is a p-type device, and wherein at least a part of the sidewall of the channel layer of the second device extends along a (110) crystal plane or a {110} crystal plane family; or
the first device is a p-type device, and at least a part of the sidewall of the channel layer of the first device extends along a (110) crystal plane or a {110} crystal plane family, wherein the second device is an n-type device, and wherein at least a part of the sidewall of the channel layer of the second device extends along a (100) crystal plane or a {100} crystal plane family.

18. The method according to claim 15, wherein,
the first device is an n-type device, the channel layer of the first device comprises a semiconductor material of one of Si, SiGe, or Ge crystals, and at least a part of the sidewall of the channel layer extends along a (100) crystal plane or a {100} crystal plane family, wherein the second device is a p-type device, the channel layer of the second device comprises a semiconductor material of one of Si, SiGe, or Ge crystals, and wherein at least a part of the sidewall of the channel layer extends along a (110) crystal plane or a {110} crystal plane family; or
the first device is a p-type device, the channel layer of the first device comprises a semiconductor material of one of Si, SiGe, or Ge crystals, and at least a part of the sidewall of the channel layer extends along a (100) crystal plane or a {110} crystal plane family, wherein the second device is an n-type device, the channel layer of the second device comprises a semiconductor material of one of Si, SiGe, or Ge crystals, and wherein at least a part of the sidewall of the channel layer extends along a (100) crystal plane or a {100} crystal plane family.

19. The method according to claim 18, wherein a direction from the first source/drain layer toward the second source/drain layer of the first device is along a [100] crystal orientation or along a <100> crystal orientation family, and/or wherein a direction from the first source/drain layer toward the second source/drain layer of the second device is along the [100] crystal orientation or along the <100> crystal orientation family.

20. The method according to claim 15, wherein,
the channel layer of the first device comprises a single crystal semiconductor material and the channel layer of the second device comprises a single crystal semiconductor material, and the channel layer of the first device has a crystal orientation the same as that of the channel layer of the second device.

21. The method according to claim 15, wherein,
the channel layer of the first device comprises a single crystal semiconductor material and the channel layer of the second device comprises a single crystal semiconductor material, and the channel layer of the first device has a crystal structure the same as that of the channel layer of the second device.

22. The method according to claim 15, wherein defining the active region of the first device comprises:
sequentially selectively etching the second source/drain layer, the channel layer and the first source/drain layer of the first device to form a pattern with sidewall extending along a first crystal plane or crystal plane family, and recessing the outer periphery of the channel layer with respect to outer peripheries of the first and second source/drain layers by isotropic etching; and
forming a sacrificial gate of the first device in a recess of the channel layer with respect to the first and second source/drain layers of the first device;
and wherein defining the active region of the second device comprises:
sequentially selectively etching the second source/drain layer, the channel layer and the first source/drain layer of the second device to form a pattern with sidewall extending along a second crystal plane or crystal plane family, and recessing the outer periphery of the channel layer with respect to outer peripheries of the first and second source/drain layers by isotropic etching; and
forming a sacrificial gate of the second device in a recess of the channel layer with respect to the first and second source/drain layers of the second device.

23. The method according to claim 22,
wherein defining the active region of the first device further comprises: rounding a sharp corner formed by adjacent sidewalls of the channel layer of the first device after the isotropic etching of the channel layer of the first device;
and/or wherein defining the active region of the second device further comprises: rounding a sharp corner formed by adjacent sidewalls of the channel layer of the second device after the isotropic etching of the channel layer of the second device.

24. The method according to claim 22, wherein after defining the active regions of the first device and the second device, the method further comprises:
forming a dopant source layer on surfaces of the first source/drain layer and the second source/drain layer of the first device; and
driving dopants from the dopant source layer into the first and second source/drain layers of the first device.

25. The method according to claim 24, wherein after defining the active regions of the first device and the second device, the method further comprises:
forming another dopant source layer on surfaces of the first source/drain layer and the second source/drain layer of the second device; and
driving dopants from the other dopant source layer into the first and second source/drain layers of the second device.

26. The method according to claim 22, wherein after forming the sacrificial gate, the method further comprises:
forming a silicide on surfaces of the first and second source/drain layers of the first device; and/or forming a silicide on surfaces of the first and second source/drain layers of the second device.

27. The method according to claim 22, wherein forming the gate stacks of the first device and the second device comprises:
forming a first isolation layer around the active regions of the first device and the second device on the substrate, wherein the first isolation layer has a top surface at a level between a top surface and a bottom surface of the channel layer;
removing the sacrificial gates of the first device and the second device to release a space in the recess of the channel layer with respect to the first and second source/drain layers;
sequentially forming a gate dielectric layer and a gate conductor layer of the first device on the first isolation layer;
etching back the gate conductor layer to remove a part of the gate conductor layer outside the recess;
removing a portion of the gate conductor layer from the recess of the channel layer with respect to the first and second source/drain layers of the second device;
forming a gate conductor layer of the second device in the recess of the second device; and
etching back the gate conductor layer of the second device, such that the gate conductor layer outside the recess has a top surface at a level lower than the top surface of the channel layer.

28. The method according to claim 27, further comprising:
forming respective gate contact pads of the first device and the second device, the gate contact pads respectively extending from the gate conductor layers of the corresponding gate stacks in a direction away from the channel layer, and the gate conductor layer and the corresponding gate contact pad of at least one of the first device or the second device comprise different materials.

29. The method according to claim 28, wherein the gate contact pads are formed using the gate conductor layer of either one of the first device or the second device.

30. The method according to claim 15, wherein providing the stack of the first source/drain layer, the channel layer, and the second source/drain layer on the substrate comprises:
epitaxially growing a first semiconductor layer on the substrate as the first source/drain layer;
epitaxially growing a second semiconductor layer on the first source/drain layer as the channel layer; and
epitaxially growing a third semiconductor layer on the channel layer as the second source/drain layer.

31. An electronic device, comprising an integrated circuit formed at least partially by the semiconductor device according to claim 1.

32. The electronic device according to claim 31, further comprising: a display cooperative with the integrated circuit and a wireless transceiver cooperative with the integrated circuit.

33. The electronic device according to claim 31, comprising at least one of a smart phone, a computer, a tablet computer, a wearable device, and/or a mobile power supply.
